(19) United States
(12) Patent Application Publication
(10) Pub. No.: US 2018/0090562 A1
(43) Pub. Date: Mar. 29, 2018

(54) SCHOTTKY BARRIER DIODE AND METHOD OF MANUFACTURING THE SAME

(71) Applicant: DONGBU HITEK CO., LTD., Seoul (KR)

(72) Inventor: Hyung Keun LEE, Suwon-si (KR)

(21) Appl. No.: 15/712,782

(22) Filed: Sep. 22, 2017

(30) Foreign Application Priority Data
Sep. 23, 2016 (KR) 10-2016-0121820

(51) Int. Cl. H01L 29/06; H01L 29/47; H01L 29/66; H01L 29/872

(52) U.S. Cl. CPC H01L 29/0619; H01L 29/872; H01L 29/66143; H01L 29/47

(57) ABSTRACT

A Schottky barrier diode includes an epitaxial layer of a first conductivity type and located on a substrate, a first well of a second conductivity type and positioned on the first conductive epitaxial layer, a plurality of first conductive layers disposed on a surface of the substrate including the first well, the first conductive layers being spaced apart from each other, an impurity region of the second conductivity type, located on the first well and disposed spaced apart outwardly from the first conductive layers and a second conductive layer located on the impurity region. The Schottky barriers disclosed improve electrical field handling and obviate the need for a p-type barrier.

### CROSS-REFERENCE TO RELATED APPLICATION

This application claims priority to Korean Patent Application No. 10-2016-0121820, filed on Sep. 23, 2016, and all the benefits accruing therefrom under 35 U.S.C. § 119, the contents of which are incorporated by reference in their entirety.

### TECHNICAL FIELD

The present invention relates to a semiconductor device, and more particularly, to a Schottky barrier diode and a method of manufacturing the Schottky barrier diode.

### BACKGROUND

Generally, a Schottky barrier diode is fabricated by forming a metal layer, such as a silicide, on a silicon region. In the Schottky barrier diode, an electric field is concentrated in the vicinity of and at an edge portion of the metal layer in the reverse mode operation, and thus, a leakage current is generated.

Thus, a P-well guard ring is formed below the edge portion of the metal layer, or a conductive electrode may be disposed on a side of the metal layer, in order to reduce the electric field at the edge portion of metal layer and to prevent leakage current. The P-well guard ring is effective to suppress the leakage current, but there is a PN junction in the silicon region so that a recovery time is increased due to unintended storage of minority carriers in a switching operation of the Schottky barrier diode, and a switching speed of the Schottky barrier diode may be delayed due to an increase in a parasitic junction capacitance.

In addition, since the Schottky barrier diode includes the P well guard ring and the conductive electrode, a structure of the Schottky barrier diode may become complicated, and an integration degree of the Schottky barrier diode may be deteriorated.

### SUMMARY

Example embodiments of the present invention provide a Schottky barrier diode having a simple structure and being capable of suppressing a leakage current due to a concentration of electric field in a reverse mode operation.

Example embodiments of the present invention provide a method of manufacturing the Schottky barrier diode.

According to an example embodiment of the present invention, a Schottky barrier diode includes an epitaxial layer having a first conductivity type and located on a substrate to define a surface, a first well having a second conductivity type and positioned on the epitaxial layer at the surface, a plurality of first conductive layers disposed on the surface and spaced apart from one another, an impurity region having the second conductivity type located on the first well and disposed spaced apart outwardly from the plurality of first conductive layers, and a second conductive layer located on the impurity region.

In an example embodiment of the present invention, at least one conductive layer of the plurality of first conductive layers is made from a material selected from the group consisting of metal and silicide.

In an example embodiment of the present invention, the first conductive layers are arranged in a stripe form or in a grid form.

In an example embodiment, the Schottky barrier diode includes an insulation layer disposed between the first conductive layers and between each of the first conductive layers and the impurity region.

In an example embodiment, the Schottky barrier diode includes device isolation layers for separating the first well from the epitaxial layer.

In an example embodiment, the Schottky barrier diode includes a second well having the second conductivity type, located in the first well below the impurity region, and the second well having a doping concentration higher than that of the first well and lower than that of the impurity region.

In the embodiments described above, the first conductive type can be p-type, and the second conductive type can be n-type.

In embodiments, the width of each of the first conductive layers can be about 0.1 μm to about 0.4 μm.

According to another embodiment, a method of manufacturing a Schottky barrier diode includes forming an epitaxial layer having a first conductivity type on a substrate; forming a first well having a second conductivity type in the epitaxial layer; forming an insulation layer having a predetermined depth in the first well to selectively expose a portion of the first well at a surface of the epitaxial layer opposite the substrate; forming an impurity region of a second conductivity type, located spaced apart outwardly from the insulation layer and in the first well; forming a plurality of first conductive layers on the portion of the first well, which is exposed by the insulation layer, to be spaced apart from each other; and forming a second conductive layer on the impurity region.

In an example embodiment, the first conductive layers can include metal silicide layers.

In an example embodiment, the first conductive layers are in stripe form or in grid form.

In an example embodiment, the method includes forming device isolation layers disposed spaced apart from the insulation layer for separating the first well from the epitaxial layer.

In example embodiments, forming the device isolation layer and the insulation layer are simultaneously performed.

In example embodiments, the method includes forming a second well of the second conductivity type, located in the first well and below the impurity region, the second well having a doping concentration higher than a doping concentration of the first well and lower than a doping concentration of the impurity region.

In example embodiments, the first conductive type is p-type, and the second conductive type is n-type.

According to the Schottky barrier diode of the present invention and the method of manufacturing the Schottky barrier diode, the first conductive layers are in a stripe shape or a grid shape, a width of each of the first conductive layers is relatively narrow. The first conductive layers are located between the insulation layers and the width of each of the first conductive layers is relatively narrow. Therefore, the electric field reduction effect which occurs at the edge portion of the first conductive film spreads throughout the first conductive layers owing to an expansion of the equipotential line of the insulation layer. Therefore, the Schottky barrier diode can reduce the electric field in the vicinity of the edge of the first conductive layers in the reverse mode operation, thereby suppressing the leakage current from occurring.

Further, it is not necessary to form a separate P-well guard ring and a conductive electrode in order to reduce the electric field in the vicinity of the edge portion of the first conductive layers. Therefore, an integration degree of the Schottky barrier diode can be improved, and the manufacturing process of the Schottky barrier diode can be simplified, thereby improving the efficiency of the Schottky barrier diode manufacturing process.

### BRIEF DESCRIPTION OF THE DRAWINGS

Example embodiments can be understood in more detail from the following description taken in conjunction with the accompanying drawings, in which:

FIG. 1 is a cross sectional view illustrating a Schottky barrier diode in accordance with an example embodiment of the present invention; and

FIGS. 2 to 6 are cross sectional views illustrating a method of manufacturing a Schottky barrier diode in accordance with example embodiments of the present invention.

### DETAILED DESCRIPTION OF THE DRAWINGS

Hereinafter, specific embodiments will be described in more detail with reference to the accompanying drawings. The present invention may, however, be embodied in different forms and should not be construed as limited to the embodiments set forth herein.

As an explicit definition used in this application, when a layer, a film, a region, or a plate is referred to as being ‘on’ another one, it can be directly on the other one, or one or more intervening layers, films, regions, or plates may also be interposed therebetween. Unlike this, it will also be understood that when a layer, a film, a region, or a plate is referred to as being ‘directly on’ another one, it is directly adjacent to the other one, and one or more intervening layers, layers, regions or plates do not exist. Also, though terms like a first, a second, and a third are used to describe various components, compositions, regions and layers, other embodiments of the present invention are not limited to these terms.

Furthermore, and solely for convenience of description, elements may be referred to as “above” or “below” one another. It will be understood that such description refers to the orientation shown in the figure being described, and that in various uses and alternative embodiments these elements could be rotated or transposed in alternative arrangements and configurations.

In the following description, the technical terms are used only for explaining specific embodiments while not limiting the scope of the present invention. Unless otherwise defined herein, all the terms used herein, which include technical or scientific terms, may have the same meaning that is generally understood by those skilled in the art.

The depicted embodiments are described with reference to schematic diagrams of some embodiments of the present invention. Accordingly, changes in the shapes of the diagrams, for example, changes in manufacturing techniques and/or allowable errors, are sufficiently expected. Accordingly, embodiments of the present invention are not described as being limited to specific shapes of areas described with diagrams and include deviations in the shapes and also the areas described. Drawings are entirely schematic and their shapes do not necessarily represent accurate shapes and may not be drawn to scale, nor are they intended to limit the scope of the present invention to the shapes and areas shown.

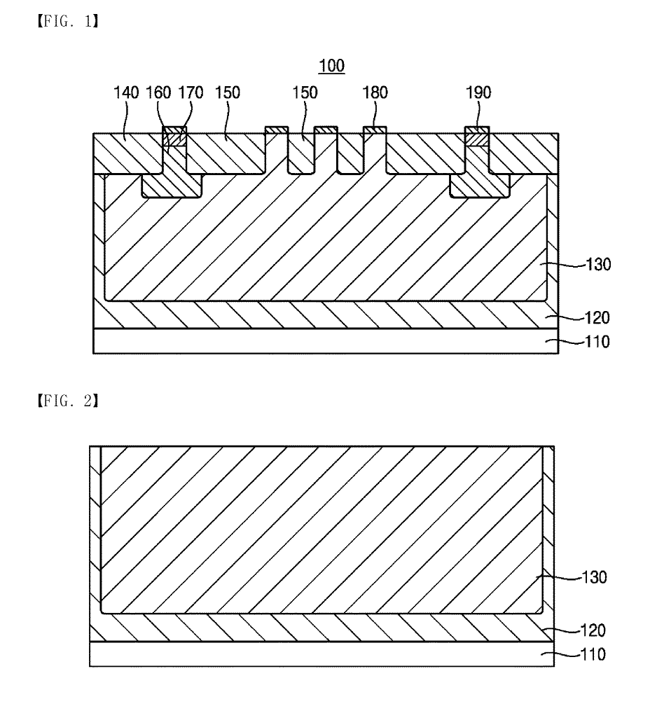

FIG. 1 is a cross sectional view illustrating a Schottky barrier diode in accordance with an example embodiment of the present invention. The Schottky barrier diode shown in FIG. 1 is a device that can be made according to the steps described below with respect to FIGS. 2-6.

Referring to FIG. 1, according to an example embodiment of the present invention, a Schottky barrier diode includes a substrate 110, an epitaxial layer 120, a first well 130, device isolation layers 140, at least one insulation layer 150, a second well 160, an impurity region 170, at least one first conductive layer 180, and a second conductive layer 190.

As shown in FIG. 1, the epitaxial layer 120 is disposed on the substrate 110. Epitaxial layer 120 has a first conductive type. The epitaxial layer 120 may be formed by an epitaxial growth process on the substrate 110. The first conductive type may be p-type in embodiments, or n-type in other embodiments. While the following description assumes that the first conductive type is p-type, one of ordinary skill in the art will recognize that in alternative embodiments the conductivity type of each component described herein could be switched in an alternative embodiment. The epitaxial layer 120 may have a base portion and an upper portion extending from the base portion vertically, as shown in FIG. 2.

The first well 130 is disposed at an upper surface portion of the epitaxial layer 120, and has a second conductive type that is different from the first conductivity type (e.g., where the epitaxial region 120 is p-type, first well 130 is n-type).

The first well 130 is arranged at a lower surface of each of the device isolation layers 140 to define an active region to a predetermined depth of the epitaxial layer 120.

Each of the device isolation layers 140 is located on a boundary between the upper portion of the epitaxial layer 120 (e.g., the portion of epitaxial layer 120 that is furthest from substrate 110) and a side portion of the first well 130, and defines an active region in the first well 130. Each of the device isolation layers 140 may have a shallow trench isolation (STI) structure or a LOCal Oxidation of Silicon (LOCOS) structure. The device isolation layers 140 may be oxide layer.

The insulation layer 150 is located in the active region and between the device isolation layers 140. The insulation layer 150 may be formed at a predetermined depth in the first well 130. The insulation layer 150 is horizontally spaced apart from the device isolation layers 140 and selectively exposes a portion of the first well 130 at a surface of the first well 130 opposite from the substrate 110. Specifically, the insulation layer 150 may have a stripe pattern to expose the portion of the first well 130 either in a stripe form or in a grid form.

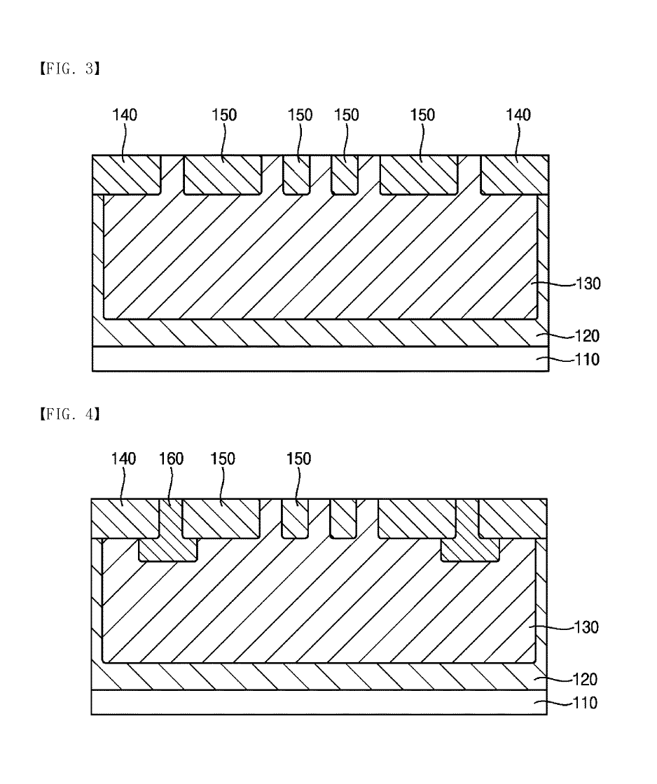

In addition or alternatively, the insulation layer 150 may be buried at a depth substantially identical to the depth of the device isolation layers 140, as shown in FIG. 3. An example of the insulation layer 150 is an oxide layer.

Referring again to FIG. 1, the second well 160 has the second conductivity type and is located inside the first well 130 between one of the device isolation layers 140 and a portion of the insulation layer 150. The second conductivity type may be n-type. The second well 160 may be formed to have a depth larger than those of the device isolation layers 140 and the insulation layer 150 (i.e., extending from the surface of first well 130 towards substrate 110 through the active region). As shown in FIG. 4, there can be multiple second wells 160 in embodiments.

The impurity region 170 has the second conductivity type, and is located between the device isolation layers 140 and the insulation layer 150. The impurity region 170 may be formed on an upper portion of the second well 160. The second conductivity type may be n-type.

The second well 160 may have a doping concentration of greater than a doping concentration of the first well 130 and less than a doping concentration of the impurity region 170. Thus, since the second well 160 is located between the first well 130 and the impurity region 170, the second well 160 can reduce a drift resistance with respect to current flow.

The first conductive layer 180 is located over the first well 130 between a plurality of portions of the insulation layer 150. That is, the first conductive layer 180 is formed on the portion of the first well 130 exposed between portions of the insulation layer 150. Accordingly, the first conductive layer 180 may be formed in multiple parts that can be spaced apart from each other in a horizontal direction in the orientation shown in FIG. 6. Since the first well 130 is exposed in a stripe form or in a grid form, the first conductive layer 180 may be in a corresponding or matching stripe form or a grid form. The first conductive layer 180 may include a metal silicide layer. The first conductive layer 180 may serve as an anode electrode.

The Schottky diode can be formed by bonding between the first well 130 and the first conductive layer 180.

Oxide of the insulation layer 150 has a relatively large dielectric constant as compared with silicon of the first conductive layer 180. A material having a large dielectric constant may have expanded equipotential lines compared with a material having a relatively small dielectric constant under similar conditions. Accordingly, the equipotential lines of the insulation layer 150 are extended at an interface between the insulation layer 150 and the first conductive layer 180.

During use, the equipotential lines of the insulation layer 150 extend to partially reach to a region of the first conductive layer 180 so that the electric field is reduced at the edge portion of the first conductive layer 180. Therefore, the electric field can be prevented from being concentrated at the edge portion of the first conductive layer 180.

Since in many embodiments the first conductive layer 180 has a stripe shape or a grid shape, a width of the first conductive layer 180 may be relatively narrow. Since the first conductive layer 180 is located between the insulation layers 150 and the width of the first conductive layer 180 is relatively narrow, the electric field reduction effect may appear throughout the first conductive layer 180. Therefore, the Schottky barrier diode 100 can reduce the electric field in the vicinity of the edge portion of the first conductive layer 180 in the reverse mode operation to suppress leakage current from occurring.

When the first conductive layer 180 has the width of less than about 0.1 μm, the width of the first conductive layer 180 is relatively narrow, so that the first conductive layer 180 may hardly function as the anode electrode.

When the first conductive layer 180 has the width of greater than about 0.4 μm, the width of the first conductive layer 180 is relatively wide, so that the electric field reduction effect is hard to appear throughout the first conductive layer 180.

Therefore, the width of the first conductive layer 180 is about 0.1 μm to about 0.4 μm so that the first conductive layer 180 functions as the anode electrode, and the electric field reducing effect appears throughout the first conductive layer 180.

The second conductive layer 190 is formed on the impurity layer 170 of the second conductive type. The second conductive layer 190 may include a metal silicide layer as the first conductive layer 180 does. The second conductive layer 190 may serve as a cathode electrode.

According to the Schottky barrier diode 100, a separate P well guard ring and a conductive electrode may not be required for reducing the electric field in the vicinity of the edge portion of the first conductive layer 180. Therefore, a structure of the Schottky barrier diode 100 is simplified, and an integration degree of the Schottky barrier diode 100 can be improved.

FIGS. 2 to 6 are cross sectional views that can also be used to illustrate a method of manufacturing a Schottky barrier diode in accordance with example embodiments of the present invention.

Referring to FIG. 2, an epitaxial layer 120 is formed on a substrate 110. The epitaxial layer 120 may be formed to have a first conductive type. The epitaxial layer 120 may formed by an epitaxial growth process. The first conductive type may be P-type.

Next, a first well 130 of a second conductivity type is formed on the epitaxial layer 120. The first well 110 is formed to a certain depth of the epitaxial layer 120. The second conductivity type may be n-type. For example, although not shown, after a photoresist pattern (not shown) is formed to expose a region of the substrate 110 where the first well 130 is to be formed, ion implantation process is performed using n-type dopant ions such as arsenic, phosphorus and the like to form the first well 130. Meanwhile, the epitaxial layer may have a base portion and an upper portion extending from the base portion vertically.

Referring to FIG. 3, device isolation layers 140 are formed for isolating the first well 130 from the epitaxial layer 120. Each of the device isolation layers 140 is located on a boundary between the upper portion of the epitaxial layer 120 and a side portion of the first well 130, and defines an active region extending across the surface of first well 130 that is opposite from the substrate 110. Each of the device isolation layers 140 may have an STI structure or a LOCOS structure. Each of the device isolation layers 140 may include an oxide layer.

According to a STI process for forming the device isolation layer 140, a trench is formed on the boundary between the upper portion of the epitaxial layer 120 and the side portion of the first well 130, and an insulation material such as oxide is buried in the trench.

An insulation layer 150 is formed to have a predetermined depth measured from a surface of the first well 130, and the insulation layer 150 is formed to selectively expose a portion of the first well 130. The insulation layer 150 is located in the active region and between the device isolation layers 140 and is horizontally spaced from the device isolation layers 140. The insulation layer 150 selectively exposes the portion of the first well 130. At this time, an exposed portion of the first well 130 may be either in a stripe form or in a grid form.

The insulation layer 150 may be formed through steps that are similar to those for forming the device isolation layer 140. Further, the device isolation layer 140 and the insulation layer 150 may be formed at the same time.

Referring to FIG. 4, a second well 160 of the second conductivity type is formed between each of the device isolation layers 140 and the insulation layer 150. The second conductivity type may be n-type.

Specifically, a first ion implantation mask (not shown) is formed to expose a surface of the first well 130 between each of the device isolation layer 140 and the insulation layer 150, and using the first ion implantation mask, impurity ions are implanted to form the second well 160. Then, the first ion implantation mask is removed.

The second well 160 is formed at a predetermined depth in the first well 130. For example, the second well 160 is formed to have a dept larger than that of the device isolation layers 140. The second well 160 may have a doping concentration higher than that of the first well 130.

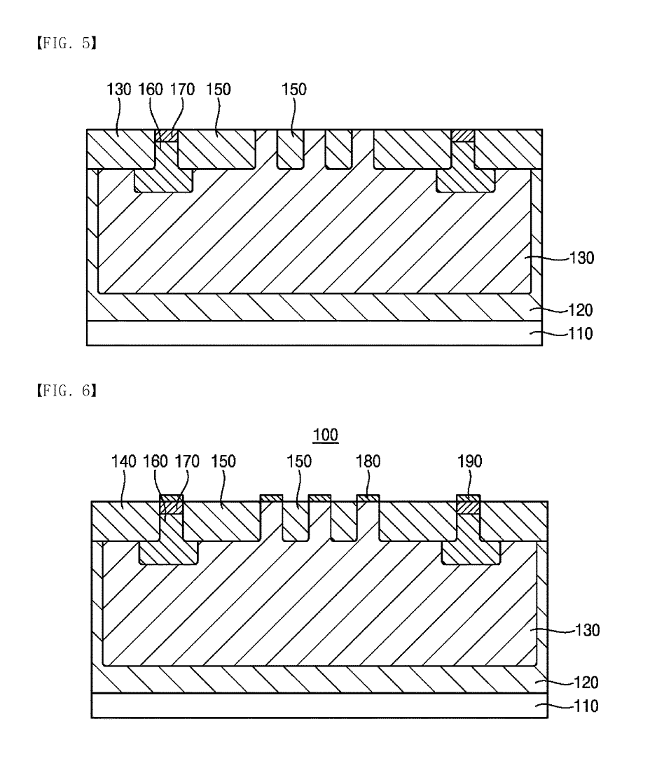

Referring to FIG. 5, an impurity region 170 of the second conductive type is formed on the second well 160 and between each of the device isolation layers 140 and the insulation layer 150. The second conductivity type may be n-type.

Specifically, a second ion implantation mask (not shown) can formed in one embodiment that will expose the second well 130 between each of the device isolation layers 140 and the insulation layer 150, and using the second ion implantation mask, impurity ions of the second conductive type can be implanted to form the impurity region 170. Then, the second ion implantation mask is removed.

In another example embodiment, after the second well 160 is formed, the impurity ions of the second conductivity type are implanted, still using the first ion implantation mask for forming the second well 160 before removing the first ion implantation mask, thereby forming the impurity region 170. Then, the first ion implantation mask is removed.

The impurity region 170 may have a doping concentration higher than that of the second well 160. Therefore, the second well 160 may have the doping concentration greater than that of the first well 130 and less than that of the impurity region 170 of second conductivity type. Thus, since the second well 160 is located between the first well 130 and the impurity region 170, the second well 160 can reduce the drift resistance with respect to current flow.

Referring to FIG. 6, a plurality of first conductive layers 180 is formed on portions of the first well 130, exposed by the insulation layer 150 such that the first conductive layer 180 are spaced apart from each other. The first conductive layers 180 may include metal silicide layers.

Further, a second conductive layer 190 is formed on the impurity region 170. The second conductive layer 190 may also include a metal silicide layer.

A mask pattern (not shown) can be formed on the device isolation layers 140 and the insulation layer 150 to expose the first well 130 and the impurity region 170 exposed by the insulation layer 150. Then, a metal layer (not shown) can be formed on the first well 130 and the impurity region 170 exposed by the first insulation layer 150. An example of the metal layer is a titanium layer.

After the metal layer is formed, heat treatment is performed at a temperature of about 650 to 750° C. for several tens of seconds against the metal layer to transform the metal layer into a metal silicide layer. A portion of the metal silicide layer, which is formed on the first well 130 exposed by the insulation layer 150, may correspond to the first conductive layer 180, and another portion of the metal silicide layer, which is formed on the impurity region 170, may correspond to the second conductive layer 190.

Since the first well 130 is exposed in a stripe form by the insulation layer 150 or exposed in a grid form, the first conductive layer 180 formed on the first well 130 exposed by the insulation layer 150, may have a stripe shape or a grid shape.

Since the first conductive layer 180 has a stripe shape or a grid shape, a width of the first conductive layer 180 is relatively narrow. Since the first conductive layer 180 is located between a plurality of the insulation layers 150 and the width of the first conductive layer 180 is relatively narrow, the electric field reduction effect appears throughout the first conductive layer 180. Therefore, the Schottky barrier diode 100 can reduce the electric field in the vicinity of the edge portion of the first conductive layer 180 in the reverse mode operation to suppress leakage current from occurring.

The first conductive layer 180 may serve as an anode electrode, and the second conductive layer 190 may serve as a cathode electrode.

Using this design, which reduces the concentration of electric fields by channeling current flow through the device 100, it is not necessary to form a separate P-well guard ring and a conductive electrode in order to reduce the electric field in the vicinity of the edge portion of the first conductive layer 180. Thus, the manufacturing process of the Schottky barrier diode is simplified, the efficiency of process for manufacturing the Schottky barrier diode can be improved.

As described above, according to the Schottky barrier diode and the method of manufacturing the Schottky barrier diode in accordance with example embodiments of the present invention, the first conductive layer is formed in a stripe shape or a grid shape, so that the electric field reduction effect which occurs at the edge portion of the first conductive layer spread throughout the first conductive layer. Therefore, the Schottky barrier diode can reduce the electric field in the vicinity of the edge portion of the first conductive film in the reverse mode operation, thereby suppressing the leakage current from occurring.

Further, it is not necessary to form a separate P-well guard ring and a conductive electrode in order to reduce the electric field in the vicinity of the edge portion of the first conductive layer. Therefore, the integration degree of the Schottky barrier diode can be improved, and the manufacturing process of the Schottky barrier diode can be simplified, thereby improving the efficiency of the Schottky barrier diode manufacturing process.

Although the Schottky barrier diodes have been described with reference to the specific embodiments, they are not limited thereto. Therefore, it will be readily understood by those skilled in the art that various modifications and changes can be made thereto without departing from the spirit and scope of the appended claims.

1. A Schottky barrier diode comprising:
an epitaxial layer having a first conductivity type and located on a substrate to define a surface;
a first well having a second conductivity type and positioned on the epitaxial layer at the surface;
a plurality of first conductive layers disposed on the surface and spaced apart from one another;
an impurity region having the second conductivity type located on the first well and disposed spaced outwardly apart from the plurality of first conductive layers; and
a second conductive layer located on the impurity region.

2. The Schottky barrier diode of claim 1, wherein at least one conductive layer of the plurality of first conductive layers is made from a material selected from the group consisting of metal and silicide.

3. The Schottky barrier diode of claim 1, wherein the first conductive layers are arranged in a stripe form or in a grid form.

4. The Schottky barrier diode of claim 1, further comprising an insulation layer disposed between the first conductive layers and between each of the first conductive layers and the impurity region.

5. The Schottky barrier diode of claim 1, further comprising device isolation layers for separating the first well from the epitaxial layer.

6. The Schottky barrier diode of claim 1, further comprising a second well having the second conductivity type, located in the first well below the impurity region, and the second well having a doping concentration higher than that of the first well and lower than that of the impurity region.

7. The Schottky barrier diode of claim 1, wherein the first conductive type is p-type, and the second conductive type is n-type.

8. The Schottky barrier diode of claim 1, wherein a width of each of the first conductive layers is about 0.1 μm to about 0.4 μm.

9. A method of manufacturing a Schottky barrier diode, comprising:
forming an epitaxial layer having a first conductivity type on a substrate;
forming a first well having a second conductivity type in the epitaxial layer;
forming an insulation layer having a predetermined depth in the first well to selectively expose a portion of the first well at a surface of the epitaxial layer opposite the substrate;
forming an impurity region of a second conductivity type, located spaced apart outwardly from the insulation layer and in the first well;
forming a plurality of first conductive layers on the portion of the first well, which is exposed by the insulation layer, to be spaced apart from each other; and
forming a second conductive layer on the impurity region.

10. The method of claim 9, wherein the first conductive layers comprise metal silicide layers.

11. The method of claim 9, wherein the first conductive layers are in stripe form or in grid form.

12. The method of claim 9, further comprising forming device isolation layers disposed spaced apart from the insulation layer for separating the first well from the epitaxial layer.

13. The method of claim 12, wherein forming the device isolation layer and the insulation layer are simultaneously performed.

14. The method of claim 9, further comprising forming a second well of the second conductivity type, located in the first well and below the impurity region, the second well having a doping concentration higher than a doping concentration of the first well and lower than a doping concentration of the impurity region.

15. The method of claim 9, wherein the first conductive type is p-type, and the second conductive type is n-type.
